(19) United States
(12) Patent Application Publication
(10) Pub. No.: US 2025/0044326 A1
(43) Pub. Date: Feb. 6, 2025

(54) OPTICALLY ISOLATED LIGHTWAVE CURRENT SENSOR

(71) Applicant: OPTILAB, LLC, Phoenix, AZ (US)

(72) Inventors: Ke Huang, Phoenix, AZ (US); Henry Hung, Paradise Valley, AZ (US); Leijun Yin, Tempe, AZ (US)

(21) Appl. No.: 18/741,501

(22) Filed: Jun. 12, 2024

Related U.S. Application Data
(60) Provisional application No. 63/517,020, filed on Aug. 1, 2023.

(51) Int. Cl. G01R 15/24; G01R 19/32

(52) U.S. Cl. CPC G01R 15/247; G01R 15/241; G01R 19/32

(57) ABSTRACT

An optically isolated lightwave current sensor including a control circuit, including: a light source configured to generate an input light beam; and a bias signal generator configured to generate an optical bias signal; a sensor head, including: an optical-to-electrical signal converter configured to convert the optical bias signal into a first electrical bias signal; a phase polarization modulator configured to phase modulate a linear polarization of at least one second light beam based on the first electrical bias signal, wherein the at least one second light beam is based on the input light beam; and an optical fiber coil optically coupled to the phase polarization modulator; and at least one optical fiber configured to route the input light beam and the optical bias signal from the control circuit to the sensor head.

### CROSS REFERENCE TO RELATED APPLICATION

This application claims the benefit of the filing date of U.S. Provisional Application, Ser. No. 63/517,020, filed on Aug. 1, 2023, which is incorporated herein by reference.

### BACKGROUND

### Field

Aspects of the present disclosure relate generally to current sensing and measurement, and in particular, to an optically isolated lightwave current sensor (OI-LCS).

### Background

A lightwave current sensor (LCS) employs a control circuit to generate an input light beam and process an output light beam received from a sensor head. The sensor head may include an optical fiber coil coaxially surrounding an electrical conductor carrying a current, wherein the optical fiber coil receives at least one circular polarized light beam. Through Faraday Effect and Sagnac interferometry, the magnetic field generated by the current phase shifts the at least one circular polarized light beam, which may be used to generate the output light beam whose intensity is a function of the current. The control circuit may process the output light beam to extract the current information.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

An aspect of the disclosure relates to an apparatus. The apparatus includes a control circuit, comprising: a light source configured to generate an input light beam; and a bias signal generator configured to generate an optical bias signal; a sensor head, comprising: an optical-to-electrical signal converter configured to convert the optical bias signal into a first electrical bias signal; a phase polarization modulator configured to phase modulate a linear polarization of at least one second light beam based on the first electrical bias signal, wherein the at least one second light beam is based on the input light beam; and an optical fiber coil optically coupled to the phase polarization modulator; and at least one optical fiber configured to route the input light beam and the optical bias signal from the control circuit to the sensor head.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIG. 1 illustrates a block diagram of an example lightwave current sensor (LCS) in accordance with an aspect of the disclosure.

FIG. 2 illustrates a block diagram of an example lightwave current sensor (LCS) for high current sensing application in accordance with another aspect of the disclosure.

FIG. 3 illustrates a block diagram of another example lightwave current sensor (LCS) for high current sensing application in accordance with another aspect of the disclosure.

FIG. 4 illustrates a block diagram of an example optically isolated lightwave current sensor (OI-LCS) in accordance with another aspect of the disclosure.

FIG. 5 illustrates a block diagram of another example optically isolated lightwave current sensor (OI-LCS) in accordance with another aspect of the disclosure.

FIG. 6 illustrates a block diagram of another example optically isolated lightwave current sensor (OI-LCS) in accordance with another aspect of the disclosure.

FIG. 7 illustrates a block diagram of an example temperature-compensating, optically isolated lightwave current sensor (OI-LCS) in accordance with another aspect of the disclosure.

FIG. 8 illustrates a side internal view of an example sensor head of a lightwave current sensor (LCS) in accordance with another aspect of the disclosure.

FIG. 9 illustrates a block diagram of a portion of an example optically isolated lightwave current sensor (OI-LCS) associated with a bias signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A lightwave current sensor (LCS) (sometimes referred to as a fiber optic current sensor (FOCS)) operates under the principle of Sagnac interferometry, where two light beams are made to propagate in opposite directions via an optical fiber coil. The two light beams undergo different circular polarization phase shifts as they propagate through the optical fiber coil. When the two light beams exit the optical fiber coil, they combine and undergo interference to form a resulting light beam whose intensity is a function of the circular polarization phase difference between the two light beams.

An LCS also operates under the principle of the Faraday effect, where a magnetic field generated by a current flowing through an electrical conductor affects the circular polarization of light beams propagating via an optical fiber. In this regard, an electrical conductor carrying a current extends coaxially through an optical fiber coil. Two circular polarized light beams are made to propagate in opposite directions through the optical fiber coil. The magnetic field of the current flowing through the electrical conductor causes phase shift between the two light beams propagating via the optical fiber coil. When the two light beams exit the optical fiber coil, they combine and undergo interference to form a resulting light beam whose intensity is a function of the phase difference between the two interfering beams, which is also a function of the current flowing through the electrical conductor.

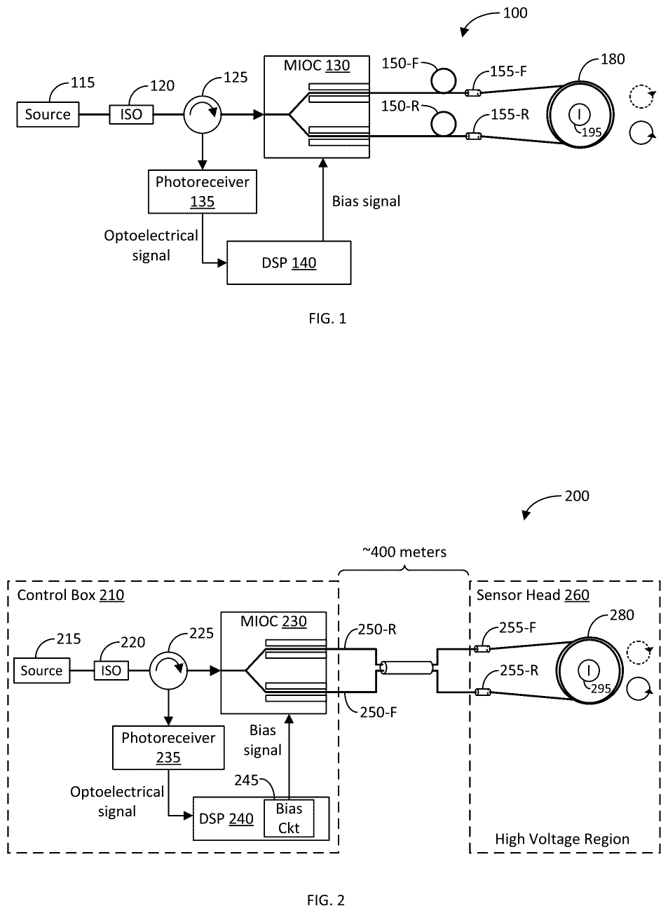

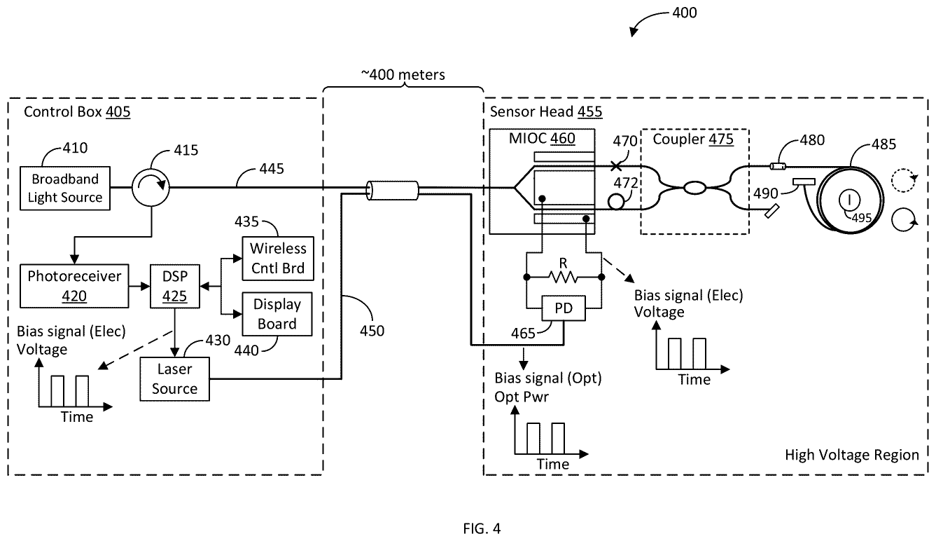

The phase difference Δϕ between the two light beams exiting the optical fiber coil may be given by the following relationship: Δϕ=2VNI (e.g., for dual-port optical fiber coils 180, 280, 380, and 685 shown in FIGS. 1, 2, 3, and 6, respectively) or Δϕ=4VNI (e.g., for single-port optical fiber coils 485, 585, and 785 shown in FIGS. 4, 5, and 7, respectively), where V is the Verdet constant of the material of the optical fiber coil, N is the number of loops in the optical fiber coil, and I is the current flowing through the electrical conductor in amperes (A). The Verdet constant is a measure of the degree of rotation of the circular polarization of a light beam propagating via the optical fiber coil with the imposed magnetic field due to the electrical current (e.g., the material's sensitivity to the Faraday effect). Various optical materials have different Verdet constant. A material that is commonly used for optical fiber coil is spun fiber, as it has a relatively high Verdet constant. The intensity or amplitude A of the resulting light beam may be given by the following relationship: A=A₀(1+cos Δϕ), where Δ₀ is the amplitude or power of either one of the two beams. The following describes various implementations of LCS.

FIG. 1 illustrates a block diagram of an example lightwave current sensor (LCS) 100 in accordance with an aspect of the disclosure. The LCS 100 includes a light (e.g., non-coherent broadband) source 115, an optical isolator 120, an optical circulator 125, a multi-functional integrated optical chip (MIOC) 120, a photoreceiver (e.g., including a photo detecting diode) 135, and a digital signal processor (DSP) 140. Additionally, the LCS 100 includes a pair of polarization maintaining (PM) optical fibers 150-F and 150-R, a pair of quarter wave (QW) retarders 155-F and 155-R, and an optical fiber coil (e.g., spun fiber) 180. The “-F” and “-R” suffixes represent forward-propagating direction and reverse-propagating directions, respectively. An electrical conductor 195, which may carry a current I, extends coaxially through the optical fiber coil 180.

The light source 115 is configured to generate an input continuous wave (CW) light beam (e.g., may also be referred to herein as an optical signal). The optical isolator (ISO) 120 allows the input CW light beam to pass through while blocking reflected and/or other light from passing through in the opposite direction towards the laser source 115. The optical circulator 125 directs the input CW light beam from the ISO 120 to a first port of the MIOC 130, while directing an output light beam (as discussed further herein) from the first port of the MIOC 130 to an input of the photoreceiver 135.

The MIOC 130, which may include a lithium niobate thin film (LNTF) optical waveguide, splits the input CW light beam into two light beams, linearly polarizes the two light beams, and induces phase polarization difference of (e.g., phase polarization modulation) the two light beams based on a bias signal (e.g., a substantially square wave signal cycling at a particular frequency (e.g., 2 megaHertz (MHz) or other, which may depend (e.g., inversely) on a length of the optical fiber coil 180)). The pair of PM optical fibers 150-F and 150-R are coupled to second and third ports of the MIOC 130 to receive the two phase-modulated linear polarized light beams, and direct the two light beams to the pair of QW retarders 155-F and 155-R, respectively. The pair of QW retarders 155-F and 155-R convert the linear polarization of the light beams into circular polarization, respectively.

The phase-modulated circular polarized light beam outputted by the QW retarder 155-F enters a first port of the optical fiber coil 180 for propagating in a forward direction therein, and the phase-modulated circular polarized light beam outputted by the QW retarder 155-R enters a second port of the optical fiber coil 180 for propagating in a reverse direction therein. In accordance with Sagnac interferometry and Faraday effect as previously discussed, the magnetic field generated by the current flowing via the electrical conductor 195 causes nonreciprocal phase shift between the two light beams propagating in opposite directions in the optical fiber coil 180.

The current-modulated forward and reverse light beams exit the optical fiber coil 180 at the second and first ports, and propagate towards the QW retarders 155-R and 155-F, respectively. The QW retarders 155-R and 155-F convert the circular polarization of the current-modulated forward and reverse light beams into linear polarization, respectively. The current-modulated forward and reverse light beams enter the third and second ports of the MIOC 130, and combine and undergo interference to form the output light beam at the first port of the MIOC 130. As previously discussed, the intensity A of the output light beam is a function of the phase difference Δϕ in the circular polarization of the forward and reverse light beams propagating in the optical fiber coil 180, which is a function of the magnetic field generated by the current flowing via the electrical conductor 195. Accordingly, the intensity A of the output light beam is a function of the current flowing through the electrical conductor 195.

The photoreceiver 135 converts the output light beam into an optoelectrical signal. The DSP 140 digitizes and processes the optoelectrical signal to generate a detection and/or measurement (e.g., information) of the current flowing through the electrical conductor 195. As shown, the DSP 140 (or other device) may also generate the bias signal provided to the MIOC 130 for applying phase polarization modulation to the two outgoing light beams, as previously discussed. The following describes the use of the LCS in high voltage/current sensing applications.

FIG. 2 illustrates a block diagram of an example lightwave current sensor (LCS) 200 for high current sensing application in accordance with another aspect of the disclosure. The LCS 200 may be deployed in high voltage (e.g., 100 to 800 kilo Volts (kV)) regions to sense high currents (e.g., 100 to 300A) associated with power distribution or other high-power applications. For example, the LCS 200 may be deployed to measure current in high voltage alternating current (HVAC) systems and/or high voltage direct current (HVDC) systems.

In particular, the LCS 200 includes a control circuit (e.g., may also be referred to herein as a “control box” or “controller”) 210 situated outside or remote from a high voltage region (e.g., a distance of ˜400 meters (m) or other from the high voltage region). The LCS 200 further includes a sensor head 260 situated within the high voltage region. As the high voltage region may not have a power source for the electronics of the LCS 200, as well as the high voltage region may not permit personnel therein during operation due to the potentially dangerous environment, it may be desirable for the components of the sensor head 260 to be passive, as explained further herein.

The control circuit 210 includes a subset of the components of the LCS 100 previously discussed, including a light source 215, an optical isolator 220, an optical circulator 225, an MIOC 230, a photoreceiver 235, and a DSP 240 including a bias circuit 245 configured to generate the bias signal. The sensor head 260 similarly includes another subset of the components of the LCS 100, including a pair of QW retarders 255-F and 255-R, and an optical fiber coil 280. An electrical conductor (e.g., an AC or DC power line) 295, associated with the high current sensing application (e.g., an HVAC and/or HVDC system), extends coaxially through the optical fiber coil 280. Additionally, the LCS 200 includes yet another subset of the components of the LCS 100, including a pair of PM or elliptical optical fibers 250-F and 250-R optically coupling the control circuit 210 to the sensor head 260.

A drawback of the LCS 200 is that the PM or elliptical optical fibers 250-F and 250-R coupling the control circuit 210 to the sensor head 260 may be very expensive because they are special optical fibers configured to maintain the linear polarization of the light beams propagating therein. Another drawback is that the Sagnac interferometry effectuated by the loop including the MIOC 230, the PM or elliptical optical fibers 250-F and 250-R, the QW retarders 255-F and 255-R, and the optical fiber coil 280, due to its long length/distance, may be susceptible to environmental perturbations, such as temperature, vibration, wind, etc. Such environmental factors may cause unwanted phase shifts in the optical signals, which may produce noise and errors in the current measurements.

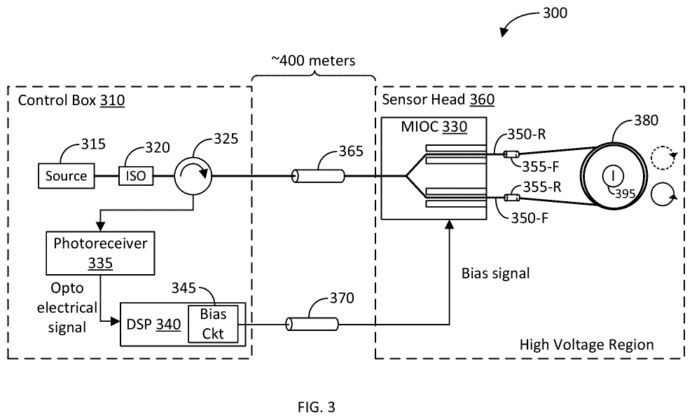

FIG. 3 illustrates a block diagram of another example lightwave current sensor (LCS) 300 for high current sensing application in accordance with another aspect of the disclosure. The LCS 300 may be a variation of the LCS 200 previously discussed. Similarly, the LCS 300 may be deployed in high voltage regions to sense high currents associated with power distribution and/or other high-power applications (e.g., HVAC and/or HVDC current sensing applications).

In this regard, the LCS 300 includes a control circuit 310 situated outside or remote from a high voltage region (e.g., a distance of ˜400 meters (m) or other from the high voltage region). The LCS 300 further includes a sensor head 360 situated within the high voltage region. As discussed, since the high voltage region may not have a power source for the electronics of the LCS 300, as well as the high voltage region not permitting personnel therein during operation due to the potentially dangerous environment, it may be desirable for the components of the sensor head 360 to be passive.

In particular, the control circuit 310 includes a subset of the components of the LCS 100 previously discussed, including a light source 315, an optical isolator 320, an optical circulator 325, a photoreceiver 335, and a DSP 340 including a bias circuit 345 configured to generate the bias signal. The sensor head 360 similarly includes another subset of the components of the LCS 100, including an MIOC 330, a pair of PM or elliptical optical fibers 350-F and 350-R, a pair of QW retarders 355-F and 355-R, and an optical fiber coil 380. An electrical conductor (e.g., an AC or DC power line) 395, associated with the high current sensing application (e.g., a HVAC and/or HVDC system), extends coaxially through the optical fiber coil 380.

Additionally, the LCS 300 includes a single-mode (SM) optical fiber 365 optically coupling the optical circulator 325 to the first port of the MIOC 330 for routing the input and output light beams therebetween. The LCS 300 further includes a radio frequency (RF) cable 370 coupling the bias circuit 345 to the MIOC 330 for routing the bias signal from the bias circuit 345 to the MIOC 330.

A drawback of the LCS 300 is that the RF cable 380 may be expensive from a material and labor perspective, especially if it has to be routed a distance of 400 meters or more or thereabouts. Additionally, for safety reasons, the RF cable 380 should be buried in the ground and include durable and high-quality electrical insulator. A qualified personnel may also be required to perform the labor to competently install the RF cable 370 in accordance with governmental regulations and standard practices.

FIG. 4 illustrates a block diagram of an example optically isolated lightwave current sensor (OI-LCS) 400 in accordance with another aspect of the disclosure. As discussed further herein, the OI-LCS 400 transmits the bias signal for the MIOC in the optical domain. Thus, the OI-LCS 400 need not have an electrical cable (e.g., an RF cable) for transmitting the bias signal from the control circuit to the sensor head. In this regard, it may be said that the LCS 400 is optically isolated because an electrical signal is not communicated from the control circuit to the sensor head. The transmission of the bias signal in the optical domain may be sent via a single-mode (SM) optical fiber, which is generally inexpensive and does not typically require expensive safety installation and material.

In particular, the OI-LCS 400 includes a control circuit 405 situated outside or remote from a high voltage region (e.g., a distance of ˜400 meters (m) or other from the high voltage region). The OI-LCS 400 further includes a sensor head 455 situated within the high voltage region. As discussed, since the high voltage region may not have a power source for the electronics of the OI-LCS 400, as well as the high voltage region not permitting personnel therein during operation due to the potentially dangerous environment, it may be desirable for the components of the sensor head 455 to be passive.

In particular, the control circuit 405 includes a light source 410, which may include an optical isolator (not shown), an optical circulator 415, a photoreceiver 420, a DSP 425, a laser source 430, a wireless control board 435, and a display board 440. In this example, the sensor head 455 includes a reflective-type optical current sensor. More specifically, the sensor head 455 includes an MIOC 460, a photodiode (PD) 465 including an associated resistor (R), a 90-degree optical splice 470, a polarization maintaining (PM) optical coupler 475, a QW retarder 480, and an optical fiber coil (e.g., spun fiber) 485 terminated with a mirror 490. An electrical conductor (e.g., an AC or DC power line) 495, associated with the high current sensing application (e.g., a HVAC and/or HVDC system), extends coaxially through the optical fiber coil 485.

Additionally, the OI-LCS 400 includes a first single-mode (SM) optical fiber 445 optically coupling the optical circulator 415 to the first port of the MIOC 460 for routing input and output light beams therebetween. The OI-LCS 400 further includes a second SM optical fiber 450 optically coupling the laser source 430 to the photodiode 465 for routing the bias signal in the optical domain from the laser source 430 to the photodiode 465. Although, in this example, two SM optical fibers 445 and 450 are used to route the input/output light beams and optical bias signal between the control circuit 405 and the sensor head 455, it shall be understood that a single SM optical fiber may be used to route both with wavelength division multiplexer/demultiplexer combining and separating the signals at the control circuit 405 and sensor head 455, respectively.

With regard to the control circuit 405, the light source 410 is configured to generate an input CW (e.g., non-coherent) light beam, the optical circulator 415 is configured to route the input light beam from the light source 410 to a first port of the MIOC 460 via the first SM optical fiber 445. Similarly, the optical circulator 415 is configured to route the output light beam received from the MIOC 460 via the first SM optical fiber 445 to the photoreceiver 420 for generating the optoelectrical signal, as previously discussed. Also, as previously discussed, the DSP 425 is configured to digitize and process the optoelectrical signal to perform a detection and/or measurement of (e.g., generate information regarding) the current sensed at the sensor head 455, as previously discussed.

The DSP 425 (or another device, such as a bias circuit) is further configured to generate the bias signal in the electrical domain for the MIOC 460, as previously discussed. The laser source 430 is configured to generate the bias signal in the optical domain based on the bias signal in the electrical domain (e.g., modulate a laser with the electrical bias signal). The laser source 430 is configured to provide the bias signal in the optical domain to the second SM optical fiber 450 for transmission to the sensor head 455, as previously mentioned.

The wireless control board 435 serves as a wireless interface for the OI-LCS 400 to transmit signals (e.g., the current and/or other information (e.g., calibration/diagnostic) to remote devices; and/or receive control and/or diagnostic/test signals from remote devices. As an example, the wireless control board 435 may use Long Range (LoRa), Global Navigation Satellite System (GNSS), and/or other protocols to communicate with such remote devices. The display board 440 may be an on-site user interface to provide information (e.g., current, calibration, diagnostic, etc.) to and/or receive information (e.g., control and/or calibration/diagnostic/test) from a user.

With regard to the sensor head 455, the photodiode 465 is configured to convert the optical bias signal received via the second SM optical fiber 450 into a current that flows through the associated resistor to regenerate the bias signal in the electrical domain. The photodiode 465 and resistor may generally be referred to as an optical-to-electrical signal converter. The MIOC 460 splits the input light beam received via the first SM optical fiber 445 into two light beams, linearly polarizes the two light beams, and phase modulate the polarization of two light beams based on the electrical bias signal. One of the phase modulated linear polarized light beam is run through a 90-degree optical splicer 470 to change its linear polarization, the other one is run through a delay line 472, and both are provided to first and second ports of the PM optical coupler 475. The PM optical coupler 475 combines both the two phase modulated linear cross-polarized light beams at a third port, and includes a fourth port that may be terminated.

The QW retarder 480 converts the linear cross-polarized polarization of the two phase-modulated light beams into opposite circular polarization light beams, respectively. The phase-modulated circular polarized light beams then enter a port of the optical fiber coil 485 and reflect off the mirror 490 transfer reversely within the optical fiber coil 485. The magnetic field generated by the current flowing through the electrical conductor 495 causes a phase shift between the two opposite circular polarization beams in the optical fiber coil 485. The current-modulated circular polarized light beams then exit the optical fiber coil 485 at the port, and are converted back into linear cross-polarized light beams by the QW retarder 480. The two beams propagate together in the same direction within the coil 485: enter the coil 485—transfer forwardly in the coil 485—reflected by the mirror 490—transfer reversely in the coil 485—exit the coil 485. The two beams have opposite circular polarization, e.g., one has clockwise circular polarization, and another one has counterclockwise circular polarization. The magnetic field causes phase shift between the two opposite circular polarizations

The current-modulated light beams then enter the PM optical coupler 475 at the third port, which are then separated and exit the PM optical coupler 475 at the first and second ports, respectively. The current-modulated light beams are again run through the 90-degree splice 470 and delay line 472, and are provided to the second and third ports of the MIOC 460, respectively. The MIOC 460 combines the current-modulated light beams, where they undergo interference to form the output light beam at the first port of the MIOC 460. As previously discussed, the output light beam propagates to the control circuit 405 via the first SM optical fiber 445, where it is converted into an optoelectrical signal, digitized, and processed to generate the current measurement information.

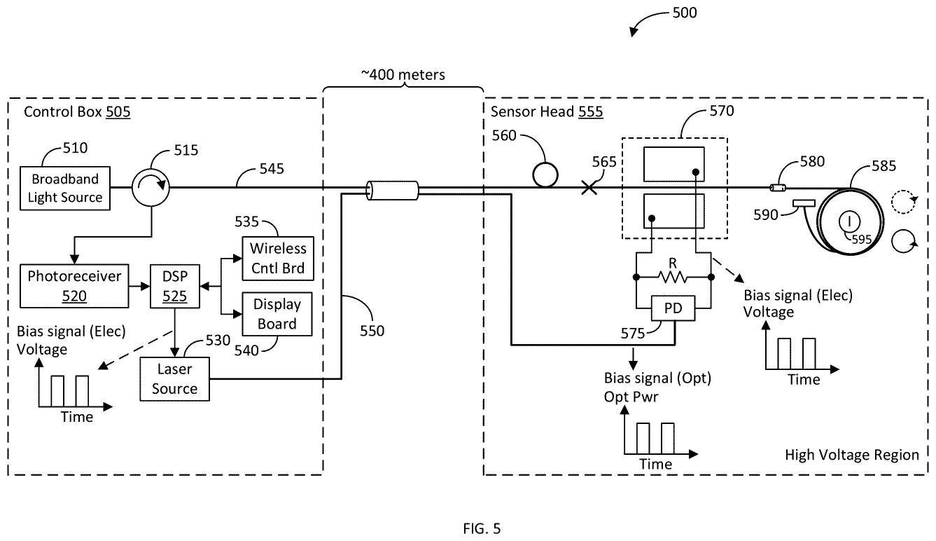

FIG. 5 illustrates a block diagram of another example optically isolated lightwave current sensor (OI-LCS) 500 in accordance with another aspect of the disclosure. Similarly, the OI-LCS 500 transmits the bias signal for a phase polarization modulator in the optical domain. Thus, the OI-LCS 500 need not have an electrical cable (e.g., an RF cable) for transmitting the bias signal from the control circuit to the sensor head. As discussed, it may be said that the LCS 500 is optically isolated because an electrical signal is not communicated from the control circuit to the sensor head. The transmission of the bias signal in the optical domain may be sent via a single-mode (SM) optical fiber, which is generally inexpensive and does not typically require expensive safety installation and material.

In particular, the OI-LCS 500 includes a control circuit 505 situated outside or remote from a high voltage region (e.g., a distance of ˜400 meters (m) or other from the high voltage region). The OI-LCS 500 further includes a sensor head 555 situated within the high voltage region. As discussed, since the high voltage region may not have a power source for the electronics of the OI-LCS 500, as well as the high voltage region not permitting personnel therein during operation due to the potentially dangerous environment, it may be desirable for the components of the sensor head 555 to be passive.

In particular, the control circuit 505 includes a light source 510, which may include an optical isolator (not shown), an optical circulator 515, a photoreceiver 520, a DSP 525, a laser source 530, a wireless control board 535, and a display board 540. In this example, the sensor head 555 includes a reflective-type optical current sensor with a phase polarization modulator instead of a MIOC. More specifically, the sensor head 555 includes a fiber polarizer 560, a 45-degree optical splice 565, a phase polarization modulator (e.g., Titanium (Ti) Diffusion type) 570, an optical-to-electrical signal converter including a photodiode (PD) 575 including an associated resistor (R), a QW retarder 580, and an optical fiber coil (e.g., spun fiber) 585 terminated with a mirror 590. An electrical conductor (e.g., an AC or DC power line) 595, associated with the high current sensing application (e.g., a HVAC and/or HVDC system), extends coaxially through the optical fiber coil 585.

Additionally, the OI-LCS 500 includes a first single-mode (SM) optical fiber 545 optically coupling the optical circulator 515 to the fiber polarizer 560 for routing input and output optical signals or light beams therebetween. The OI-LCS 500 further includes a second SM optical fiber 550 optically coupling the laser source 530 to the photodiode 575 for routing the bias signal in the optical domain from the laser source 530 to the photodiode 575. Although, in this example, two SM optical fibers 545 and 550 are used to route the input/output light beams and optical bias signal between the control circuit 505 and the sensor head 555, it shall be understood that a single SM optical fiber may be used to route both with wavelength division multiplexer/demultiplexer combining and separating the signals at the control circuit 505 and sensor head 555, respectively.

With regard to the control circuit 505, the light source 510 is configured to generate an input CW (e.g., non-coherent) light beam, the optical circulator 515 is configured to route the input light beam from the light source 510 to the fiber polarizer 560 via the first SM optical fiber 545. Similarly, the optical circulator 515 is configured to route the output light beam received from the fiber polarizer 560 via the first SM optical fiber 545 to the photoreceiver 520 for generating the optoelectrical signal, as previously discussed. Also, as previously discussed, the DSP 525 is configured to digitize and process the optoelectrical signal to perform a detection and/or measurement of the current sensed at the sensor head 555 (e.g., generate the current information), as previously discussed.

The DSP 525 (or another device, such as a bias circuit) is further configured to generate the bias signal in the electrical domain for the phase polarization modulator 570. The laser source 530 is configured to generate the bias signal in the optical domain based on the bias signal in the electrical domain (e.g., modulate a laser with the electrical bias signal). The laser source 530 is configured to provide the bias signal in the optical domain to the second SM optical fiber 550 for transmission to the sensor head 555.

The wireless control board 535 serves as a wireless interface for the OI-LCS 500 to transmit signals (e.g., current and/or other information (e.g., calibration/diagnostic)) to remote devices; and/or receive control and/or calibration/diagnostic/test signals from remote devices. As an example, the wireless control board 535 may use LoRa, GNSS, and/or other protocols to communicate with such remote devices. The display board 540 may be an on-site user interface to provide information (e.g., current, calibration, diagnostic, etc.) to and/or receive information (e.g., control and/or calibration/diagnostic/test) from a user.

With regard to the sensor head 555, the fiber polarizer 560 linearly polarizes the input light beam received from the control circuit 505 via the first SM optical fiber 545, which is then run through the 45-degree optical splice 565 to create linear cross-polarized light beams. The photodiode 575 is configured to convert the optical bias signal received via the second SM optical fiber 550 into a current that flows through the associated resistor to regenerate the bias signal in the electrical domain. The phase polarization modulator 570 phase modulate the linear cross-polarized light beams based on the electrical bias signal.

Because of the 45-degree splice 565 is situated before the phase polarization modulator 570, the phase polarization modulator 570 sees two cross polarized linear beams, and these beams propagate to the QW retarder 580, which converts them into a clockwise circular polarized light beam and counterclockwise circular polarized beam, respectively. The two phase-modulated circular polarized light beams then enter a port of the optical fiber coil 585 and reflect off the mirror 590 to transfer reversely within the optical fiber coil 585. As previously discussed, the magnetic field generated by the current flowing through the electrical conductor 595 causes a phase shift between the two opposite polarization beams in the optical fiber coil 585. The current-modulated circular polarized light beam then exists the optical fiber coil 585 at the port, and is converted back into linear cross-polarized light beams by the QW retarder 580.

The current-modulated light beam is run through the phase polarization modulator 570, 45-degree splice 565, and fiber polarizer 560 to form the output light beam. As previously discussed, the output light beam propagates to the control circuit 505 via the first SM optical fiber 545, where it is converted into an optoelectrical signal, digitized, and processed to generate the current measurement information.

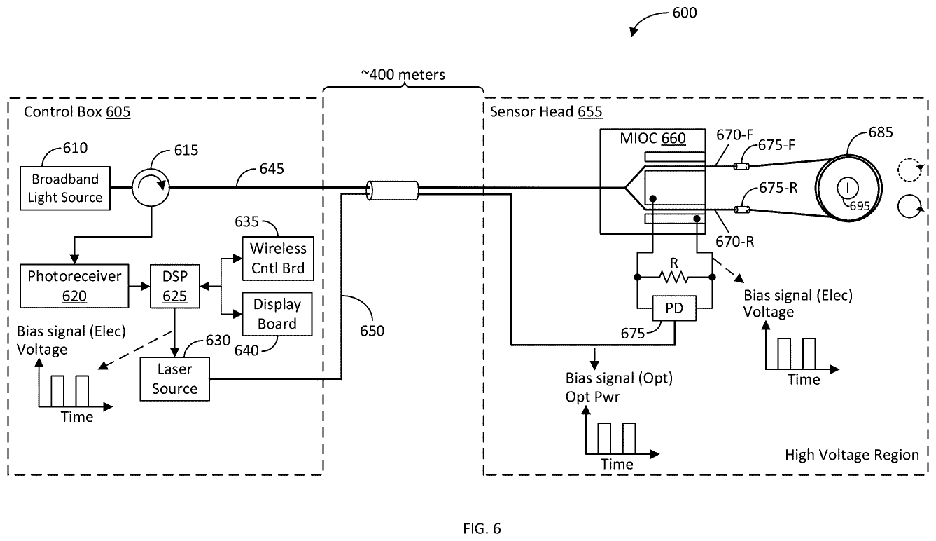

FIG. 6 illustrates a block diagram of another example optically isolated lightwave current sensor (OI-LCS) 600 in accordance with another aspect of the disclosure. Similarly, the OI-LCS 600 transmits the bias signal for the MIOC in the optical domain. Thus, the OI-LCS 600 need not have an electrical cable (e.g., an RF cable) for transmitting the bias signal from the control circuit to the sensor head. As discussed, it may be said that the OI-LCS 600 is optically isolated because an electrical signal is not communicated from the control circuit to the sensor head. The transmission of the bias signal in the optical domain may be sent via a single-mode (SM) optical fiber, which is generally inexpensive and does not typically require expensive safety installation and material.

In particular, the OI-LCS 600 includes a control circuit 605 situated outside or remote from a high voltage region (e.g., a distance of ˜400 meters (m) or other from the high voltage region). The OI-LCS 600 further includes a sensor head 655 situated within the high voltage region. As discussed, since the high voltage region may not have a power source for the electronics of the OI-LCS 600, as well as the high voltage region not permitting personnel therein during operation due to the potentially dangerous environment, it may be desirable for the components of the sensor head 655 to be passive.

In particular, the control circuit 605 includes a light source 610, which may include an optical isolator (not shown), an optical circulator 615, a photoreceiver 620, a DSP 625, a laser source 630, a wireless control board 635, and a display board 640. In this example, the sensor head 655 includes a basic Sagnac interferometer configuration using an MIOC, as previously discussed. More specifically, the sensor head 655 includes an MIOC 660, an optical-to-electrical signal converter including a photodiode (PD) 675 and an associated resistor (R), a pair of PM or elliptical optical fibers 670-F and 670-R, a pair of QW retarders 675-F and 675-R, and an optical fiber coil (e.g., spun fiber) 685. An electrical conductor (e.g., an AC or DC power line) 695, associated with the high current sensing application (e.g., a HVAC and/or HVDC system), extends coaxially through the optical fiber coil 685.

Additionally, the OI-LCS 600 includes a first single-mode (SM) optical fiber 645 optically coupling the optical circulator 615 to a first port of the MIOC 660 for routing input and output light beams therebetween. The OI-LCS 600 further includes a second SM optical fiber 650 optically coupling the laser source 630 to the photodiode 665 for routing the bias signal in the optical domain from the laser source 630 to the photodiode 665. Although, in this example, two SM optical fibers 645 and 650 are used to route the input/output light beams and the optical bias signal between the control circuit 605 and the sensor head 655, it shall be understood that a single SM optical fiber may be used to route both with wavelength division multiplexer/demultiplexer combining and separating the signals at the control circuit 605 and sensor head 655, respectively.

With regard to the control circuit 605, the light source 610 is configured to generate an input CW (e.g., non-coherent) light beam, the optical circulator 615 is configured to route the input light beam from the light source 610 to the MIOC 660 via the first SM optical fiber 645. Similarly, the optical circulator 615 is configured to route the output light beam received from the MIOC 660 via the first SM optical fiber 645 to the photoreceiver 620 for generating the optoelectrical signal, as previously discussed. Also, as previously discussed, the DSP 625 is configured to digitize and process the optoelectrical signal to perform a detection and/or measurement of the current sensed at the sensor head 655 (e.g., generate the current information), as previously discussed.

The DSP 625 (or another device, such as a bias circuit) is further configured to generate the bias signal in the electrical domain for the MIOC 660. The laser source 630 is configured to generate the bias signal in the optical domain based on the bias signal in the electrical domain (e.g., modulate a laser with the electrical bias signal). The laser source 630 is configured to provide the bias signal in the optical domain to the second SM optical fiber 650 for transmission to the sensor head 655.

The wireless control board 635 serves as a wireless interface for the OI-LCS 600 to transmit signals (e.g., current and/or other information (e.g., calibration and/or diagnostic information)) to remote devices; and/or receive control and/or calibration/diagnostic/test signals from remote devices. As an example, the wireless control board 635 may use LoRa, GNSS, and/or other protocols to communicate with such remote devices. The display board 640 may be an on-site user interface to provide information (e.g., current detection/measurement, calibration, diagnostic, etc.) to and/or receive information (e.g., control and/or calibration/diagnostic/test) from a user.

With regard to the sensor head 655, the photodiode 665 is configured to convert the optical bias signal received via the second SM optical fiber 650 into a current that flows through the associated resistor to regenerate the bias signal in the electrical domain. The MIOC 660 is configured to split the input light beam received from the control circuit 605 via the first SM optical fiber 645, linearly polarized the two light beams, and phase modulate the linear polarization of the two light beams based on the bias signal generated by the photodiode 665 and associated resistor.

The pair of PM or elliptical optical fibers 670-F and 670-R route the phase-modulated, linear polarized light beams from the MIOC 660 to the pair of QW retarders 675-F and 675-R, respectively. The pair of QW retarders 675-F and 675-R convert the linear polarization of the light beams into circular polarization. The phase-modulated circular polarized light beams from the pair of QW retarders 675-F and 675-R enter the optical fiber coil 685 at first and second ports for propagating in opposite directions therein. In accordance with Sagnac interferometry and Faraday effect previously discussed, the magnetic field generated by the current flowing via the electrical conductor 695 causes a phase shift between the two light beams propagating in opposite directions in the optical fiber coil 685.

The current-modulated light beams exit the optical fiber coil 685 at the second and first ports, and propagate towards the QW retarders 675-R and 675-F, respectively. The QW retarders 675-R and 675-F convert the circular polarization of the current-modulated light beams into linear polarization, respectively. The current-modulated linear polarized light beams enter the MIOC 660 via the pair of PM or elliptical optical fibers 670-F and 675-R, and combine and undergo interference to form the output light beam at the first port of the MIOC 660. The output light beam propagates to the control circuit 605 via the first SM optical fiber 645, where it is converted into an optoelectrical signal, digitized, and processed to generate the current measurement information.

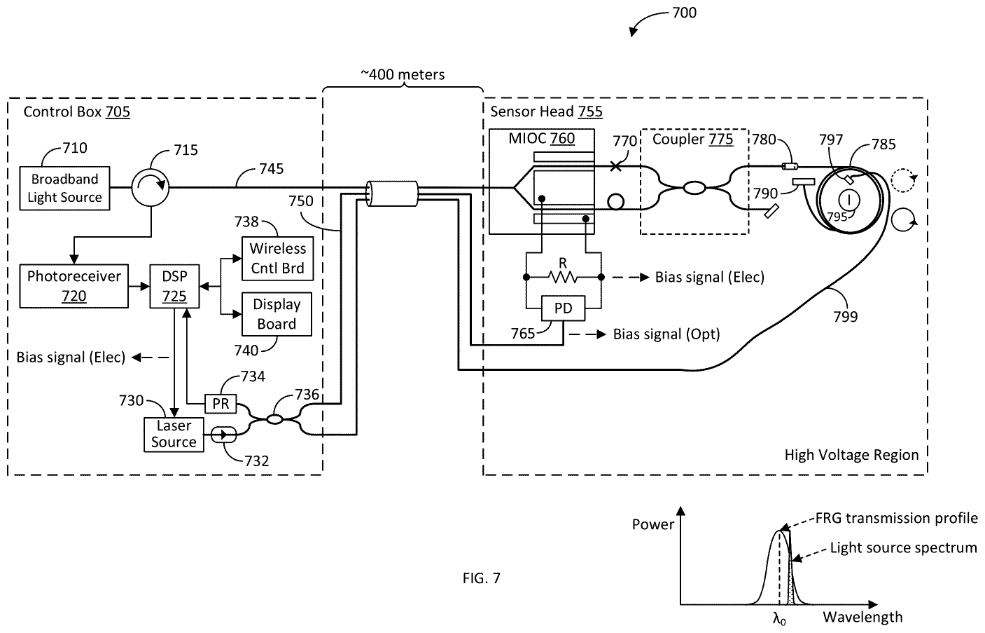

FIG. 7 illustrates a block diagram of another example temperature-compensating, optically isolated lightwave current sensor (OI-LCS) 700 in accordance with another aspect of the disclosure. The environment temperature at a sensor head affects the phase relation between the two opposite circularly polarized light beams within an optical fiber coil. For example, the phase difference Δϕ(T) in the circular polarization of the light beams with temperature (T) may be given as follows: Δϕ(T)=2NIV(T)sin(δ(T))/δ(T), where V(T) is the Verdet constant of the optical fiber coil as a function of the temperature T, and δ(T) is the linear birefringence of the optical fiber coil as a function of the temperature T. Such temperature-dependent phase difference Δϕ(T) affects the accurate measurement of the sensed current.

Accordingly, the temperature-compensated OI-LCS 700 is similar to the OI-LCS 400 previously discussed with additional components to effectuate the temperature compensating as discussed further herein. Accordingly, the temperature-compensated OI-LCS 700 includes many same/similar elements as the OI-LCS 400 as indicated by the same reference numbers with the exception that the most significant digit is a “7” in OI-LCS 700 instead of a “4” as in OI-LCS 400. Further, although the temperature compensation is provided to the OI-LCS 400 in OI-LCS 700, it shall be understood that same/similar temperature compensation may be provided to OI-LCS 500 and 600.

With regard to temperature compensation, the sensor head 755 includes a temperature sensor (e.g., a Fiber Bragg Grating (FBG) temperature sensor) 797, which may be coupled to or integrated with a single-mode (SM) optical fiber 799 that extends from the sensor head 755 to the control circuit 705. The control circuit 705, in turn, includes a fiber coupler 736, a photoreceiver (PR) 734, and an optical isolator 732. The optical isolator 732 is configured to pass through the optical signal generated by the laser source 730, while preventing reflected light, for example, off the fiber coupler 736, from propagating back to the laser source 730.

The fiber coupler 736 directs the optical signal generated by the laser source 730 for bias signal and temperature-sensing applications towards the sensor head 755 via the SM optical fibers 750 and 799, respectively. The fiber coupler 736 also directs the temperature-compensating optical signal reflected off the FBG temperature sensor 797 and received via the SM optical fiber 799 towards the photoreceiver 734. The power of the temperature-compensating optical signal is a function of the environment temperature at the sensor head 755. The reflection window of the FBG temperature sensor 797 is shifted according to the temperature, as shown in the right below region in the FIG. 7. When the window shifts towards right, the reflected light power increases. When the window shifts to left, the reflected power decreases. So, the photoreceiver 734 generates an electrical signal with an amplitude proportional to the optical power it sees, and the optical power is related to the sensed temperature. The DSP 725 digitizes and processes the electrical signal to temperature-compensate the optoelectrical signal generated by the photoreceiver 720 to arrive at a more accurate current measurement.

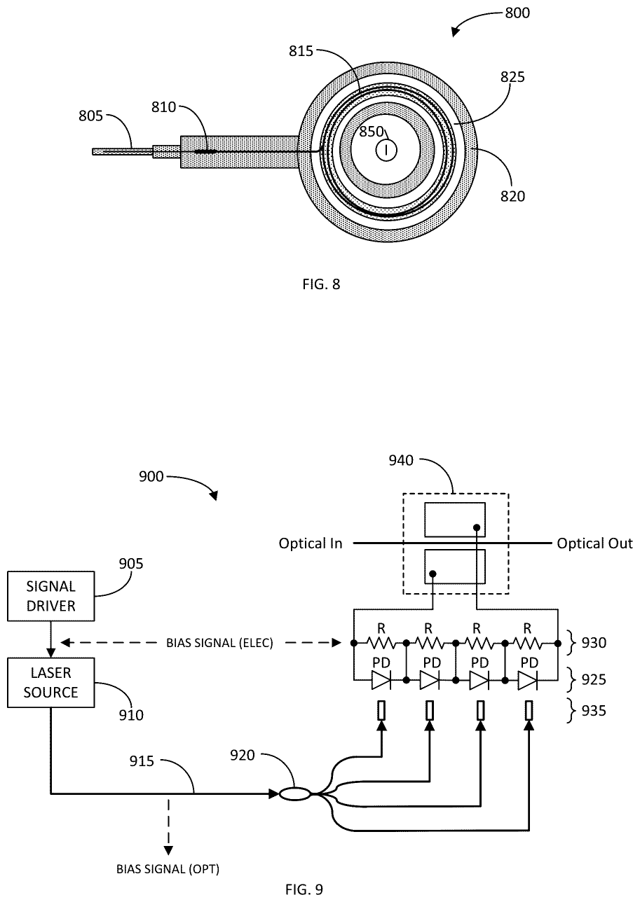

FIG. 8 illustrates a side internal view of an example sensor head 800 of a lightwave current sensor (LCS) in accordance with another aspect of the disclosure. Another approach to address the environment temperature at the sensor head is to heat insulate or isolate the optical fiber coil (e.g., spun fiber) 815. In this regard, the sensor head 800 includes a one or more polarization maintaining (PM) or elliptical optical fibers 805 to route one or more optical signals to and from the optical fiber coil 815, as previously discussed. Also depicted, the sensor head 800 includes one or more QW retarders 810 optically coupled between the PM or elliptical optical fiber 805 and the optical fiber coil 815, also as previously discussed.

The sensor head 800 includes a non-metallic sensor coil housing 820 for coaxially enclosing the optical fiber coil 815. The sensor coil housing 820 forms a coaxial channel or opening through which an electrical conductor 850 configured to carry an electrical current to be measured extends, as previously discussed. The sensor coil housing 820 further includes heat insulating or isolating material 825 in proximity to (e.g., substantially surrounding) the optical fiber coil 815. An example of a heat insulating or isolating material is a silicon-dioxide (SiO₂) aerogel, which is electrically non-conductive and has a relatively low thermal conductivity. It shall be understood that the thermally-insulated or isolated sensor head 800 may be used in combination with the temperature-compensating solution of OI-LCS 700.

FIG. 9 illustrates a block diagram of a portion of an example optically isolated lightwave current sensor (OI-LCS) 900 associated with a bias signal in accordance with another aspect of the disclosure. The OI-LCS 900 includes a signal driver or bias circuit 905 configured to generate an electrical bias signal for a phase polarization modulator 940 or an MIOC, as previously discussed. The OI-LCS 900 further includes a laser source 910 configured to generate an optical bias signal for transmission to a sensor head via a single-mode (SM) optical fiber 915.

The OI-LCS 900 also includes an optical-to-electrical signal converter including a set of series-coupled photodiodes (PD) 925 configured to receive the optical bias signal, and generate a set of currents based on the optical bias signal. Additionally, the optical-to-electrical signal converter further includes a set of resistors (R) 930 coupled in parallel with the set of series-coupled photodiodes 925, respectively. The set of resistors 930 are configured to produce voltages in response to the currents generated by the set of series-coupled photodiodes 925 based on the optical bias signal, respectively. As the set of resistors 930 are also coupled in series with respect to each other, the voltages add to produce an electrical bias signal across the set of resistors 930. The phase polarization modulator 940 or MIOC is coupled across the set of resistors 930 to receive the electrical bias signal. Thus, the number of photodiodes/resistors may be used to set the amplitude of the electrical bias signal for the phase polarization modulator 940 or MIOC.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. An apparatus, comprising:
a control circuit, comprising:
a light source configured to generate an input light beam; and
a bias signal generator configured to generate an optical bias signal;
a sensor head, comprising:
an optical-to-electrical signal converter configured to convert the optical bias signal into an electrical bias signal;
a phase polarization modulator configured to phase modulate a linear polarization of at least one second light beam based on the electrical bias signal, wherein the at least one second light beam is based on the input light beam; and
an optical fiber coil optically coupled to the phase polarization modulator; and
at least one optical fiber configured to route the input light beam and the optical bias signal from the control circuit to the sensor head.

2. The apparatus of claim 1, wherein the optical-to-electrical signal converter comprises:
a photodiode configured to generate a current based on the optical bias signal; and
a resistor configured to generate the electrical bias signal based on the current.

3. The apparatus of claim 1, wherein the optical-to-electrical signal converter comprises:
a set of photodiodes configured to generate a set of currents based on the optical bias signal; and
a set of resistors configured to generate a set of voltages based on the set of currents, respectively, wherein the electrical bias signal is based on the set of voltages.

4. The apparatus of claim 1, wherein the at least one optical fiber comprises at least one single-mode optical fiber.

5. The apparatus of claim 1, wherein the phase polarization modulator comprises a multi-functional integrated optical chip (MIOC).

6. The apparatus of claim 5, wherein the MIOC is configured to:
split the input light beam into two light beams; and
linearly polarize and phase modulate the linear polarization of the two light beams based on the electrical bias signal.

7. The apparatus of claim 6, wherein the sensor head further comprises a pair of quarter wave (QW) retarders configured to generate two phase-modulated circularly polarized light beams based on the phase-modulated linearly polarized light beams, respectively.

8. The apparatus of claim 7, wherein the sensor head further comprises a pair of polarization maintaining (PM) or elliptical optical fibers coupled between the MIOC and the pair of QW retarders, respectively.

9. The apparatus of claim 7, where the optical fiber coil includes two ports configured to receive the two phase-modulated circularly polarized light beams, respectively.

10. The apparatus of claim 9, wherein phases of the two phase-modulated circularly polarized light beams is modulated by current flowing through an electrical conductor extending coaxially through the optical fiber coil.

11. The apparatus of claim 10, wherein the pair of QW retarders are further configured to generate two current-modulated linearly polarized light beams based on the two current-modulated circularly polarized light beams received from the optical fiber coil, respectively.

12. The apparatus of claim 11, wherein the MIOC is further configured to combine the two current-modulated linearly polarized light beams to undergo interference and generate an output light beam.

13. The apparatus of claim 6, wherein the sensor head further comprises:
an optical splice configured to change the linear polarization of one of the phase-modulated linearly polarized light beams;
an optical coupler configured to combine the two phase-modulated linearly polarized light beams; and
a quarter wave (QW) retarder configured to generate phase-modulated opposite circularly polarized light beams based on the two phase-modulated linearly polarized light beams.

14. The apparatus of claim 13, wherein the optical splice comprises a 90-degree optical splice coupled between the MIOC and the optical coupler.

15. The apparatus of claim 13, wherein the optical fiber coil includes a first end configured to receive the two phase-modulated opposite circularly polarized light beams, and a second end terminating at a mirror.

16. The apparatus of claim 15, wherein phases of the phase-modulated circularly polarized light beam and a reflected phase-modulated circularly polarized light beam off the mirror are modulated by current flowing through an electrical conductor extending coaxially through the optical fiber coil.

17. The apparatus of claim 16, wherein the QW retarder is further configured to generate a current-modulated linearly polarized light beam based on the current-modulated circularly polarized light beam received from the optical fiber coil.

18. The apparatus of claim 17, wherein:
the optical coupler is configured to split the current-modulated linearly polarized light beam into two current-modulated linearly polarized light beams; and
the MIOC is further configured to combine the two current-modulated linearly polarized light beams to undergo interference and generate an output light beam.

19. The apparatus of claim 1, wherein the sensor head further includes a polarizer configured to linearly polarize the input light beam to generate the at least one second light beam.

20. The apparatus of claim 19, wherein the sensor head further comprises a 45-degree optical splice configured to generate the at least one second light beam including linearly cross-polarized light beams based on the input light beam.

21. The apparatus of claim 19, wherein the sensor head further comprises a quarter wave (QW) retarder configured to generate a phase-modulated circularly polarized light beam based on the at least one second light beam.

22. The apparatus of claim 21, wherein the optical fiber coil includes a first end configured to receive the phase-modulated circularly polarized light beam, and a second end terminating at a mirror.

23. The apparatus of claim 22, wherein phases of the phase-modulated circularly polarized light beam and a reflected phase-modulated circularly polarized light beam off the mirror are modulated by current flowing through an electrical conductor extending coaxially through the optical fiber coil.

24. The apparatus of claim 23, wherein the QW retarder is further configured to generate a current-modulated linearly polarized light beam based on the current-modulated circularly polarized light beam received from the optical fiber coil.

25. The apparatus of claim 1, wherein the sensor head is configured to generate an output light beam based on circularly polarized light beams propagating in opposite directions in the optical fiber coil whose phases are modulated by a current flowing through an electrical conductor extending coaxially through the optical fiber coil.

26. The apparatus of claim 25, wherein the control circuit further comprises a first photoreceiver configured to generate an optoelectrical signal based on the output light beam received from the sensor head via the at least one optical fiber.

27. The apparatus of claim 26, wherein the control circuit further comprises a processor configured to process the optoelectrical signal to generate information regarding the current flowing through the electrical conductor.

28. The apparatus of claim 27, wherein:
the processor is further configured to generate a second electrical bias signal; and
the bias signal generator is configured to generate the optical bias signal based on the second electrical bias signal.

29. The apparatus of claim 27, wherein:
the sensor head further comprises a fiber Bragg grating (FBG) temperature sensor configured to generate an optical signal related to a temperature at the sensor head;
the control circuit further comprises a second photoreceiver configured to generate an electrical signal based on the optical signal received from the sensor head via the at least one optical fiber; and
the processor is configured to process the electrical signal to temperature compensate the optoelectrical signal in generating the information regarding the current flowing through the electrical conductor.

30. The apparatus of claim 1, wherein the sensor head further comprises a housing to enclose the optical fiber coil, wherein the housing further includes thermal insulating or isolating material proximate the optical fiber coil.

31. The apparatus of claim 30, wherein the thermal insulating or isolating material comprises a silicon dioxide (SiO₂) aerogel.
